(19) United States
(12) Patent Application Publication
(10) Pub. No.: US 2008/0150005 A1
(43) Pub. Date: Jun. 26, 2008

(54) MEMORY SYSTEM WITH DEPLETION GATE

(75) Inventors: Meng Ding, Sunnyvale, CA (US); YouSeok Suh, Cupertino, CA (US); Wei Zheng, Santa Clara, CA (US); Kuo-Tung Chang, Saratoga, CA (US)

Correspondence Address: LAW OFFICES OF MIKIO ISHIMARU, 333 W. EL CAMINO REAL, SUITE 330, SUNNYVALE, CA, 94087, US

(73) Assignee: SPANSION LLC, Sunnyvale, CA (US)

(21) Appl. No.: 11/694,089

(22) Filed: Mar. 30, 2007

Related U.S. Application Data
(60) Provisional application No. 60/871,431, filed on Dec. 21, 2006.

(51) Int. Cl. H01L 29/792

(52) U.S. Cl. 257/324; 257/E29.309

(57) ABSTRACT

A memory system includes a substrate, forming a first insulator layer over the substrate, forming a charge-storage layer over the first insulator layer, forming a second insulator layer over the charge-storage layer, and forming a depletion gate having a depletion phenomenon over the second insulator layer.

### CROSS-REFERENCE TO RELATED APPLICATION(S)

This application claims the benefit of U.S. Provisional Patent Application Ser. No. 60/871,431 filed Dec. 21, 2006.

### TECHNICAL FIELD

The present invention relates generally to memory systems, and more particularly to a system for non-volatile memory.

### BACKGROUND ART

Across all aspects of modern life, there has been a proliferation of electronics, such as smart phones, personal digital assistants, location based devices, digital cameras, or music players. The utility of these electronics continue to require increasing amounts of data storage, such as phone numbers, digital pictures, or music files. The need for longer usage times and lower power consumption has increased the need for non-volatile storage. Numerous technologies have been developed to meet these requirements.

Various types of non-volatile memories have been developed including electrically erasable programmable read only memory (EEPROM) and electrically programmable read only memory (EPROM). Each type of memory had advantages and disadvantages. EEPROM can be easily erased without extra exterior equipment but with reduced data storage density, lower speed, and higher cost. EPROM, in contrast, is less expensive and has greater density but lacks erasability.

Another type of memory called “Flash” EEPROM, or Flash memory, has become popular as it combines advantages of high density and low cost characteristic of EPROM but with the electrical erasability of EEPROM. Flash memory can be rewritten and hold its contents without supplying continuous power. Contemporary Flash memories are designed in a floating gate or a charge trapping architecture. Each of the architectures has advantages and disadvantages.

The floating gate architecture offers implementation simplicity. This architecture embeds a gate structure, called a floating gate, inside a conventional metal oxide semiconductor (MOS) transistor gate stack. Electrons can be injected and stored in the floating gate as well as erased using an electrical field or ultraviolet light. The stored informing may be interpreted as a value “0” or “1” from the threshold voltage value depending upon charge stored in the floating gate. As the demand for Flash memories increases, the Flash memories must scale with new semiconductor processes. However, new semiconductor process causes a reduction of key feature sizes in Flash memories of the floating gate architecture that result in decrease in data retention.

There continue to be concerns regarding the erasing and programming processes, since too high a voltage or too much current can damage the memory cell. In order to perform an erase without damaging the memory cell a process of erase, verify, and repeat is used. This iterative approach helps to protect the individual memory cells, but severely restricts the performance of the memory array.

Similarly, when data is programmed into the memory cell it is difficult to accurately end the write process at the proper resistance value. Applying too much current may damage the memory cell and applying too little current yields unreliable data retention. This conventional approach of updating memory cells is too slow. The erasing and programming limitations present significant issues to non-volatile memory manufacturers. A new approach must be found in order to increase the performance of non-volatile memory.

Thus, a need still remains for a memory system to improve programming performance, and erasing performance. In view of the ever-increasing commercial competitive pressures, along with growing consumer expectations and the diminishing opportunities for meaningful product differentiation in the marketplace, it is critical that answers be found for these problems. Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a substrate, forming a first insulator layer over the substrate, forming a charge-storage layer over the first insulator layer, forming a second insulator layer over the charge-storage layer and forming a depletion gate having a depletion phenomenon over the second insulator layer.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional isometric view of a memory system in an embodiment of the present invention;

FIG. 2 is a cross-sectional view of the memory cell stack;

FIG. 3 is a cross-sectional view of the structure of FIG. 2 in a first insulator forming phase;

FIG. 4 is a cross-sectional view of the structure of FIG. 3 in a charge layer forming phase;

FIG. 5 is a cross-sectional view of the structure of FIG. 4 in a second insulator forming phase;

FIG. 6 is a cross-sectional view of the structure of FIG. 5 in a depletion gate forming phase;

FIG. 7 is an erase performance graph;

FIG. 8 is a programming performance graph;

FIGS. 9A, 9B, and 9C are schematic views of electronics systems as examples in which various aspects of the present invention can be implemented; and

FIG. 10 is a flow chart of a memory system for manufacturing the memory system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Where multiple embodiments are disclosed and described, having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the invention, regardless of its orientation. The term “vertical” refers to a direction perpendicular to the horizontal as just defined. Terms, such as “on” “above”, “below”, “bottom”, “top”, “side” (as in “sidewall”), “higher”, “lower”, “upper”, “over”, and “under”, are defined with respect to the horizontal plane.

The term “on” as used herein means and refers to direct contact among elements. The term “processing” as used herein includes deposition of material, patterning, exposure, development, etching, cleaning, and/or removal of the material or trimming as required in forming a described structure. The term “system” as used herein means and refers to the method and to the apparatus of the present invention in accordance with the context in which the term is used.

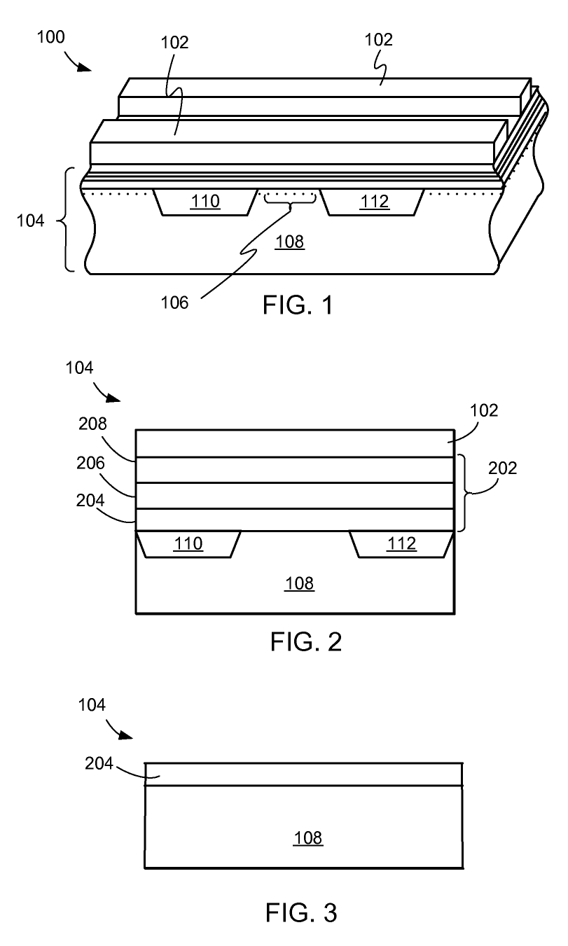

Referring now to FIG. 1, therein is shown a cross-sectional isometric view of a memory system 100 in an embodiment of the present invention. The memory system 100 may be used in a number of different memory architectures, such as NOR or NAND architecture. The memory system 100 includes a depletion gate 102, such as an N+ polysilicon gate, providing a control gates in cooperation with bit lines (not shown) for decoding processes, such as reading, programming, and erasing. The dopant concentration for forming the depletion gate 102 can be about 5×10¹⁹/cm³ or between about 8×10¹⁸/cm³ and about 1×10¹²/cm³.

The memory system 100 includes a memory cell stack 104 including a charge storage region 106 for storing an electrical charge, such as electrons. For illustrative purposes, the memory system 100 is shown having the charge storage region 106 in one location for storing electrical charges, although it is understood that any number of the charge storage regions may be included. It is also understood that the charge storage region 106 may provide storage for any number of electrical charges.

The memory cell stack 104 can also includes a semiconductor substrate 108, such as a p-type substrate, having a first region 110, such as an n-type region, and a second region 112, such as an n-type region. The first region 110 can function as a source or a drain while the second region 112 can function as a drain or a source though the compliment of the first region 110. The first region 110, the second region 112, or a combination thereof can connect to bit lines (not shown) providing access in to the memory system 100 for decoding processes. Signals on the depletion gate 102 and connection of the bit lines to an electrical source or drain can enable the memory system 100 to read, program or erase the charge storage region 106.

It has been discovered that the memory system 100 with the depletion gate 102 provides significantly improved programming speed.

Referring now to FIG. 2, therein is shown a cross-sectional view of the memory cell stack 104. The memory cell stack 104 includes a charge-storage stack 202 on the semiconductor substrate 108. The charge-storage stack 202 provides a region between the first region 110 and the second region 112 for storage of electrical charges. The semiconductor substrate 108 and the depletion gate 102 provide access for reading and erasing storage locations of electrical charges. The depletion gate 102 is formed over the charge-storage stack 202.

The charge-storage stack 202 can include multiple layers. A first insulator layer 204, such as a dielectric layer of silicon dioxide (SiO₂), of the charge-storage stack 202 is formed over the semiconductor substrate 108. A charge-storage layer 206, such as charge trap layer of silicon rich nitride (SiRN) or standard nitride (Si_{X}N_{Y}), of the charge-storage stack 202 is formed over the first insulator layer 204. The charge-storage layer 206 provides one or more regions for storage of electrical charges. A second insulator layer 208, such as a dielectric layer of silicon dioxide (SiO₂), of the charge-storage stack 202 is formed over the charge-storage layer 206. For illustrative purposes, the charge-storage layer 206 is shown as one layer although it is understood that any number of layers may be used for the charge-storage layer 206.

It has been discovered that the memory system 100 with the charge-storage layer 206 having silicon-rich nitride provides significantly improved erase speed.

Referring now to FIG. 3, therein is shown a cross-sectional view of the structure of FIG. 2 in a first insulator forming phase. The memory cell stack 104 formed between the first region 110 of FIG. 1 and the second region 112 of FIG. 1 includes the first insulator layer 204. The first insulator layer 204 can be formed as an oxide, such as silicon dioxide (SiO₂), over the semiconductor substrate 108. The first insulator layer 204 can be formed from an upper portion of the semiconductor substrate 108 by a number of processes, such as chemical vapor deposition process, thermal oxidation, or steam oxidation. The first insulator layer 204 can serve as a blocking oxide layer providing blocking of injected charges.

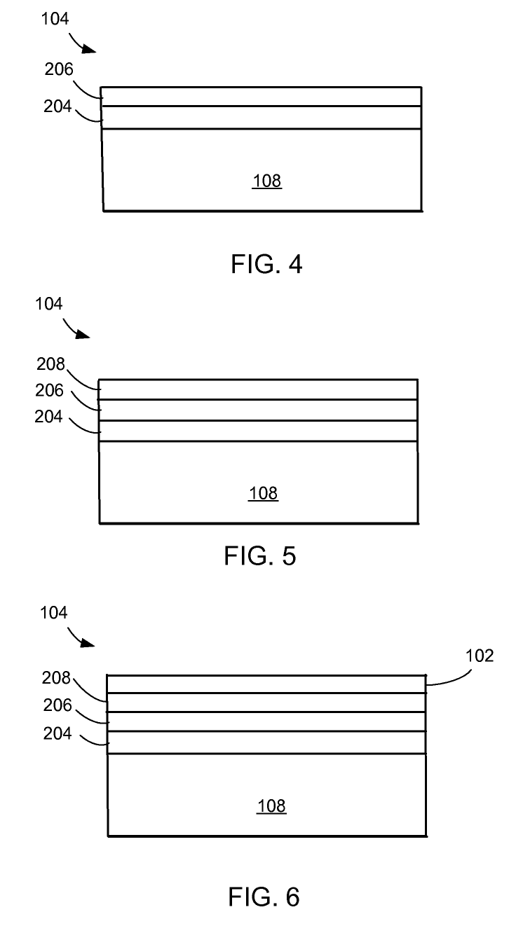

Referring now to FIG. 4, therein is shown a cross-sectional view of the structure of FIG. 3 in a charge layer forming phase. The charge-storage layer 206 can be deposited over the first insulator layer 204 and the semiconductor substrate 108. The charge-storage layer 206 can be formed by several processes such as a chemical vapor deposition process (CVD) wherein two types of gases, such as NH₃ and SiH₄, interact during the deposition of the silicon-rich nitride. A ratio of the gases, such as NH₃:SiH₄, can be below approximately 360:60, but higher than approximately 53:330, to be considered silicon-rich nitride. The silicon-rich nitride can also include a higher ratio, such as 28:360, to provide conductivity for single bit storage.

Referring now to FIG. 5, therein is shown a cross-sectional view of the structure of FIG. 4 in a second insulator forming phase. As an example, the second insulator layer 208 can be formed as an oxide, such as silicon dioxide (SiO₂), over the charge-storage layer 206 and the semiconductor substrate 108. The second insulator layer 208 can be formed from an upper portion of the charge-storage layer 206 by a number of processes, such as chemical vapor deposition process, thermal oxidation, or steam oxidation. The second insulator layer 208 can serve as a blocking oxide layer providing blocking of injected charges particularly at a top interface between oxide and nitride layers. Blocking injected charges at the top interface can significantly improve erase performance.

Referring now to FIG. 6, therein is shown a cross-sectional view of the structure of FIG. 5 in a depletion gate forming phase. The depletion gate 102 is formed over the second insulator layer 208 as a top blocking oxide layer. A forming process, such as applying a dopant to the depletion gate 102, enables the depletion gate 102 to exhibit a depletion phenomenon. The depletion phenomenon is defined as creation of a region without charge carriers. Further, the doping process can provide depletion of the depletion gate 102, such as at positive gate bias. The depletion phenomenon of the depletion gate 102 improves programming performance including significantly shorter programming times and significantly higher programming voltages.

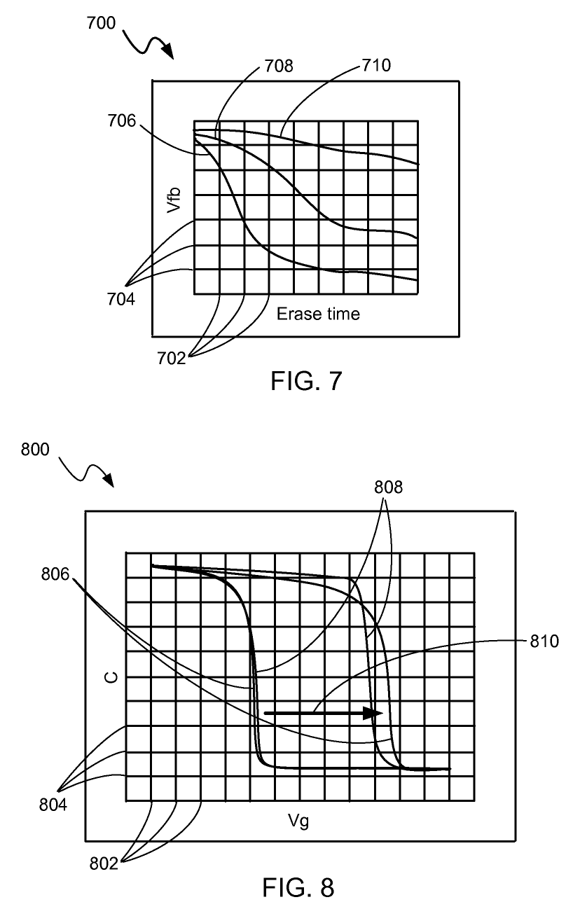

Referring now to FIG. 7, therein is shown an erase performance graph 700. The erase performance graph 700 includes erase times 702 and flash bit voltages 704. The memory system 100 of FIG. 1 having the charge-storage layer 206 of FIG. 2 includes silicon-rich nitride. A high silicon richness plot 706 of the memory system 100 including the charge-storage layer 206 having high richness depicts the erase times 702 significantly shorter than a medium silicon richness plot 708. A low silicon richness plot 710 depicts the erase times 702 beyond a range of the erase performance graph 700 with the flash bit voltages 704 remaining at a high level indicating that an erase has not been performed. The charge-storage layer 206 having silicon-rich nitride greatly enhances erasing speed.

Referring now to FIG. 8, therein is shown a programming performance graph 800. The programming performance graph 800 includes gate voltages 802 and capacitances 804. The memory system 100 of FIG. 1 having the depletion gate 102 of FIG. 1 includes a depletion phenomenon. A high depletion plot pair 806 depicts a steeper slope at an erase state and a higher level of the gate voltages 802 at a program state than a low depletion plot pair 808 with limited or no depletion phenomenon.

The steeper slope at the erase state indicates a substantially full discharge of the capacitances 804 and a higher programming level of the gate voltages 802 indicating significantly faster programming and significantly deeper level of a program 810 of the memory system 100. The depletion gate 102 decreases an electric field at program near the second insulator layer 208 and an interface of the charge-storage layer 206 thus decreasing the gate escape from the depletion gate 102, while not impeding electron injection from the semiconductor substrate 108.

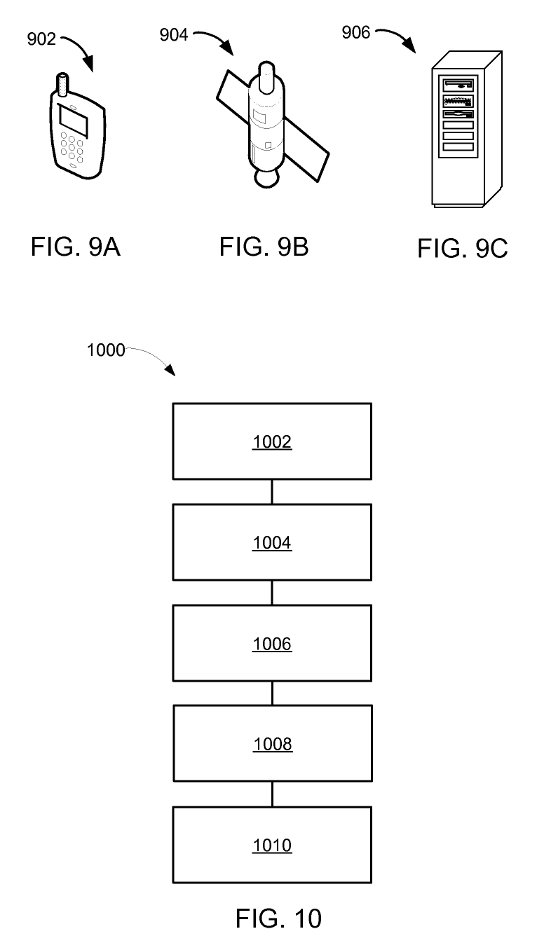

Referring now to FIGS. 9A, 9B, and 9C therein is shown schematic views of electronics systems as examples in which various aspects of the present invention can be implemented. The electronics systems can be any system performing any function including creation, transportation, transmittal, modification, or storage of data. As examples, electronics systems such as a smart phone 902, a satellite 904, and a compute system 906 can include the present invention. For example, information created, transported, or stored on the smart phone 902 can be transmitted to the satellite 904. Similarly, the satellite 904 can transmit or modify the information to the compute system 906 wherein the information can be stored, modified, or transmitted by the compute system 906.

Referring now to FIG. 10, therein is shown a flow chart of a memory system 1000 for manufacturing the memory system 100 in an embodiment of the present invention. The system 1000 includes providing a substrate 1002; forming a first insulator layer over the substrate in a block 1004; forming a charge-storage layer over the first insulator layer in a block 1006; forming a second insulator layer over the charge-storage layer in a block 1008; and forming a depletion gate having a depletion phenomenon over the second insulator layer in a block 1010.

In greater detail, a system to provide the method and apparatus of the memory system 100, in an embodiment of the present invention, is performed as follows:
1. Providing a semiconductor substrate having a first region and a second region.
2. Forming a first insulator layer over the first region and the second region of the semiconductor substrate.
3. Forming a charge-storage layer as a nitride layer over the first insulator layer.
4. Forming a second insulator layer as an oxide on the charge-storage layer.
5. Forming a depletion gate having a dopant for a depletion phenomenon over the second insulator layer.

The present invention thus has numerous aspects.

A principle aspect is that the depletion gate exhibiting the depletion phenomenon provides significantly improved programming performance. The depletion gate provides significantly faster programming and significantly deeper programming.

Another aspect is that the present invention is that silicon-rich nitride significantly improves erase performance. The charge-storage layer having silicon-rich nitride greatly enhances erasing speed.

Another aspect of the present invention is that the second insulator layer can inhibit gate injection and block charges injected from the silicon at a top oxide-nitride interface, resulting in faster and deeper erase.

Yet another aspect of the present invention is that the charge-storage layer may be tuned with respect to silicon content to balance erase performance, program performance, and data retention.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the memory system method and apparatus of the present invention furnish important and heretofore unknown and unavailable solutions, capabilities, and functional aspects for memory systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A memory system comprising:
providing a substrate;
forming a first insulator layer over the substrate;
forming a charge-storage layer over the first insulator layer;
forming a second insulator layer over the charge-storage layer; and
forming a depletion gate having a depletion phenomenon over the second insulator layer.

2. The system as claimed in claim 1 wherein forming the depletion gate includes applying a dopant on a gate to provide the depletion phenomenon.

3. The system as claimed in claim 1 wherein forming the charge-storage layer includes forming a nitride layer for storing a charge.

4. The system as claimed in claim 1 wherein forming the first insulator layer includes forming an oxide layer for insulating the charge-storage layer.

5. The system as claimed in claim 1 further comprising forming an electronics system including the memory system.

6. A memory system comprising:
providing a semiconductor substrate having a first region and a second region;
forming a first insulator layer over the first region and the second region of the semiconductor substrate;
forming a charge-storage layer as a nitride layer over the first insulator layer;
forming a second insulator layer as an oxide on the charge-storage layer; and
forming a depletion gate having a dopant for a depletion phenomenon over the second insulator layer.

7. The system as claimed in claim 6 wherein forming the depletion gate includes applying an N+ dopant on a gate to provide the depletion phenomenon.

8. The system as claimed in claim 6 wherein forming the charge-storage layer includes forming a silicon rich nitride layer for storing a charge.

9. The system as claimed in claim 6 wherein forming the first insulator layer includes forming a silicon dioxide layer for insulating the charge-storage layer.

10. The system as claimed in claim 6 wherein forming the second insulator layer includes forming a silicon dioxide layer for insulating the charge storage-layer.

11. A memory system comprising:
a substrate;
a first insulator layer over the substrate;
a charge-storage layer over the first insulator layer;
a second insulator layer over the charge-storage layer; and
a depletion gate having a depletion phenomenon over the second insulator layer.

12. The system as claimed in claim 11 wherein the depletion gate includes a dopant on a gate to provide the depletion phenomenon.

13. The system as claimed in claim 11 wherein the charge-storage layer is a nitride layer for storing a charge.

14. The system as claimed in claim 11 wherein the first insulator layer is an oxide layer for insulating the charge-storage layer.

15. The system as claimed in claim 11 further comprising an electronics system including the memory system.

16. The system as claimed in claim 11 wherein:
the substrate is a semiconductor substrate having a first region and a second region;
the first insulator layer is over the first region and the second region of the semiconductor substrate;
the charge-storage layer is a nitride layer;
the second insulator layer is an oxide on the charge-storage layer; and
the depletion gate is a depletion gate having a dopant.

17. The system as claimed in claim 16 wherein the depletion gate includes an N+ dopant on a gate to provide the depletion phenomenon.

18. The system as claimed in claim 16 wherein the charge-storage layer includes a silicon rich nitride layer for storing a charge.

19. The system as claimed in claim 16 wherein the first insulator layer is a silicon dioxide layer for insulating the charge-storage layer.

20. The system as claimed in claim 16 wherein the second insulator layer is a silicon dioxide layer for insulating the charge storage-layer.
